(19) United States
(12) Patent Application Publication
(10) Pub. No.: US 2005/0212054 A1
(43) Pub. Date: Sep. 29, 2005

(54) Semiconductor device and method of manufacturing the same

(75) Inventor: Shingo Hashimoto, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 11/085,201

(22) Filed: Mar. 22, 2005

(30) Foreign Application Priority Data
Mar. 29, 2004 (JP) 2004-095919

(51) Int. Cl. H01L 27/10

(52) U.S. Cl. 257/368

(57) ABSTRACT

The semiconductor device includes a memory cell which has a SRAM structure including a pair of drive transistors where the gate electrode of one of the pair of drive transistors is connected to the drain of the other of the pair of drive transistors via a node interconnect on which a resistor is provided. The gate electrode of one of the pair of the drive transistors has a salicide structure including a semiconductor layer, and a silicide layer formed on a surface of the semiconductor layer other than a connection region. The node interconnect formed on the gate electrode at the connection region is connected with the gate electrode.

This application is based on Japanese Patent application No.2004-095919, the content of which is incorporated hereinto by reference.

### BACKGROUND OF THE INVENTION

1. Field of the Invention

The present invention relates to a semiconductor device and a method of manufacturing the same, particularly to a semiconductor device including a semiconductor memory device such as a static random access memory including a resistor and a method of manufacturing the same.

2. Description of the Related Art

In accordance with the recent growing demands for a micronization of chips or memory cells of SRAMs (static random access memory) and higher integration level of semiconductor devices, increase in soft error rate (SER) of an SRAM has become a problem. The reason why the SER occurs will be described in the following. When alpha ray or cosmic ray penetrates the semiconductor substrate, on which the SRAM including a memory cell is formed, many electron-hole pairs are generated. The electron-hole pairs are collected to the gate of one of the pair of the N-MOS transistors to change the electric potential of the storage node connected to the N-MOS transistor from high (H) to low (L). This causes the electric potential of the storage node connected to the other of the pair of the N-MOS transistors to change from low (L) to high (H). Therefore, the data stored in the memory cell is affected.

In order to reduce the influence in SER, there is provided a technique to provide a resistance or a capacity at the storage node of the memory cell such that even when the electric potential of one of the storage nodes is changed from H to L caused by alpha ray or cosmic ray, the electric potential of the other of the storage nodes is not easily changed because of the time constant CR determined by the characteristics of the resistor and the capacity.

It is disclosed in Japanese Laid-open patent publication 2003-60087 that the gate electrode of a MOS transistor which is not connected to a resistor has a salicide structure including a semiconductor layer and a metal-semiconductor combination layer while the gate electrode of a MOS transistor which is connected to a resistor includes only a semiconductor layer to have the resistance of the semiconductor layer function as the resistor.

It is disclosed in Japanese Laid-open patent publication 2000-269338 that contact holes are opened at the positions of an inter-layer insulating film formed on a salicide semiconductor element and non-salicide one, corresponding to the formation positions of the salicide semiconductor element and the non-salicide one, a barrier metal is coated on the internal surface of the inter-layer insulating film and the contact hole, and the barrier metal which is coated on the internal surface of the contact hole opened corresponding to the formation position of the non-salicide semiconductor element is removed. According to the publication, it is said that a semiconductor device by which a layout area of a semiconductor element which requires a high resistance is reduced can be obtained.

It is disclosed in Japanese Laid-open patent publication H02-150062 that a high resistance region is formed on a part of a semiconductor layer of a gate electrode, wherein the dosage of impurities at the high resistance region is controlled to be lower than the other parts.

It is disclosed in Japanese Laid-open patent publication 2004-13920 that a layered structure of a polysilicon layer and a metal layer is formed at the connection part of the gate of a MOS transistor and a node wherein the layered structure functions as a resistor.

The techniques disclosed in the above publications relate to a method of forming a high resistance region at a part of a low resistance region. Thus, in order to actualize the techniques disclosed in the above publications, a lithography technique is necessary. However, it is difficult to form the high resistance region in the memory cell of SRAM which has fine patterns. In addition, in order to avoid the influence to the low resistance region of the memory cell, the margin region is necessary when the high resistance region is formed by the lithography technique. This causes increase in size of the memory cell.

### SUMMARY OF THE INVENTION

According to the present invention, there is provided a semiconductor device, comprising: a conductive layer having a connection region where a salicide is not formed, said conductive layer further having a salicide structure which surrounds at least a part of said connection region; a contact plug, a bottom surface of which is formed on said connection region and a side surface of which is in contact with said salicide structure; and an interconnect layer coupled to said contact plug.

In the semiconductor device of the present invention, said conductive layer may be a gate electrode of a static random access memory (SRAM) cell.

In the semiconductor device of the present invention, said SRAM cell has a pair of drive transistors, said interconnect layer may be coupled between one of said drive transistors and the other of said drive transistors.

According to the present invention, there is provided a semiconductor device, comprising: a conductive layer which has a salicide structure including a semiconductor layer, and a silicide layer formed on a surface of said semiconductor layer other than a connection region; and a contact formed on said connection region of said conductive layer for connecting said conductive layer to an upper interconnect. It means that the silicide layer is not formed on the connection region of the conductive layer. Thus, the contact is directly connected with the semiconductor layer. The contact resistance of the semiconductor layer and the contact serves as a resistance. The semiconductor layer may be constituted of a polysilicon layer.

In the semiconductor device of the present invention, said conductive layer may be a gate electrode of a MOS transistor.

The semiconductor device of the present invention, may further comprise a memory cell which has a SRAM structure including a pair of drive transistors (or driver transistors) where the gate electrode of one of said pair of drive transistors is connected to the drain of the other of said pair of drive transistors via a node interconnect on which a resistor is provided. In the semiconductor device, said conductive layer may be said gate electrode of said one of said pair of drive transistors and said contact may be said node interconnect formed on said gate electrode. The resistor is actualized by the contact resistance of the semiconductor layer and the contact.

The semiconductor device of the present invention may further comprise an inter layer dielectric formed on said conductive layer to cover thereof, wherein said inter layer dielectric may be provided with a contact hole and said connection region of said conductive layer may be defined by the pattern of said inter layer dielectric.

The semiconductor device of the present invention may further comprise an etching stopper, constituted of a material which has high etching selectively to said silicide layer, formed on said inter layer dielectric, wherein said etching stopper may be formed to have same shape as that of said inter layer dielectric.

According to the present invention, there is provided a method for manufacturing a semiconductor device, comprising: forming a conductive layer which has a salicide structure including a semiconductor layer, and a silicide layer formed on a surface of said semiconductor layer; forming an inter layer dielectric on said conductive layer to cover said conductive layer; forming a contact hole in said inter layer dielectric to expose a part of said silicide layer of said conductive layer; etching said exposed silicide layer with using said inter layer dielectric as a mask for a self alignment process to remove said part of said silicide layer; and forming a contact in said contact hole for connecting said conductive layer to an upper inter connect. The contact is connected directly with the semiconductor layer of the conductive layer.

According to the present invention, there is provided a method for manufacturing a semiconductor device including a memory cell which has a SRAM structure including a pair of drive transistors where the gate electrode of one of said pair of drive transistors is connected to the drain of the other of said pair of drive transistors via a node interconnect on which a resistor is provided, comprising: forming a plurality of transistors each including a gate electrode which has a salicide structure including a semiconductor layer, and a silicide layer formed on a surface of said semiconductor layer, and source and drain regions, said plurality of transistors including said pair of drive transistors; forming an inter layer dielectric on said plurality of transistors; forming a contact hole in said inter layer dielectric to expose a part of said silicide layer of said gate electrode of said drive transistor; etching said exposed silicide layer with using said inter layer dielectric as a mask for a self alignment process to remove said part of said silicide layer; and forming a contact which is electrically connected to said gate electrode in said contact hole and functions as said node interconnect.

In the method for manufacturing a semiconductor device of the present invention, a plurality of contact holes may be formed in said forming a contact hole, and said method may further comprises: forming a mask to cover said plurality of contact holes other than said contact hole formed on said part of said silicide layer of said gate electrode of said drive transistor; and removing said mask after said etching said exposed silicide layer.

The method for manufacturing a semiconductor device of the present invention, may further comprise forming an etching stopper, constituted of a material which has high etching selectively to said silicide layer, on said inter layer dielectric, wherein said contact hole may be formed in said etching stopper as well in said forming a contact hole.

According to the semiconductor device of the present invention, the silicide layer is not formed at the part of the conductive layer or the gate electrode where the upper interconnect or the node interconnect is to be connected and the conductive layer or the gate electrode is directly connected to the upper interconnect or the node interconnect. Thus, the contact resistance therebetween is not lowered compared with the case when the silicide layer is formed therebetween. Thus, the structure in which a resistor having high resistance is provided on the upper interconnect or the node interconnect can be obtained.

According to the method for manufacturing a semiconductor device of the present invention, the silicide layer is selectively etched by using the inter layer dielectric formed with a contact hole as a mask for a self alignment process. Therefore, the high accuracy lithography techniques are not necessary. Therefore, the semiconductor device of the present embodiment can be obtained with a simple manufacturing process. In addition, by using the self alignment process, margin regions are not necessary. Therefore, the size of the semiconductor device is not increased.

### BRIEF DESCRIPTION OF THE DRAWINGS

The above and other objects, advantages and features of the present invention will be more apparent from the following description taken in conjunction with the accompanying drawings, in which:

FIG. 1 shows an equivalent circuit of a semiconductor device of the present invention;

FIGS. 2A, 2B, and 2C show layouts of the semiconductor device including the memory cell MC as described in FIG. 1;

FIGS. 3A and 3B show cross sectional views of A-A line and B-B line of the structure shown in FIGS. 2A to 2C, respectively;

FIGS. 4A to 4C are cross sectional views of the semiconductor device as described above, showing the manufacturing process of the memory cell MC; and

FIGS. 5A to SC are cross sectional views of the semiconductor device of the embodiment, showing the manufacturing process of the memory cell MC.

### DETAILED DESCRIPTION OF THE PREFERRED EMBODIMENT

The present invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

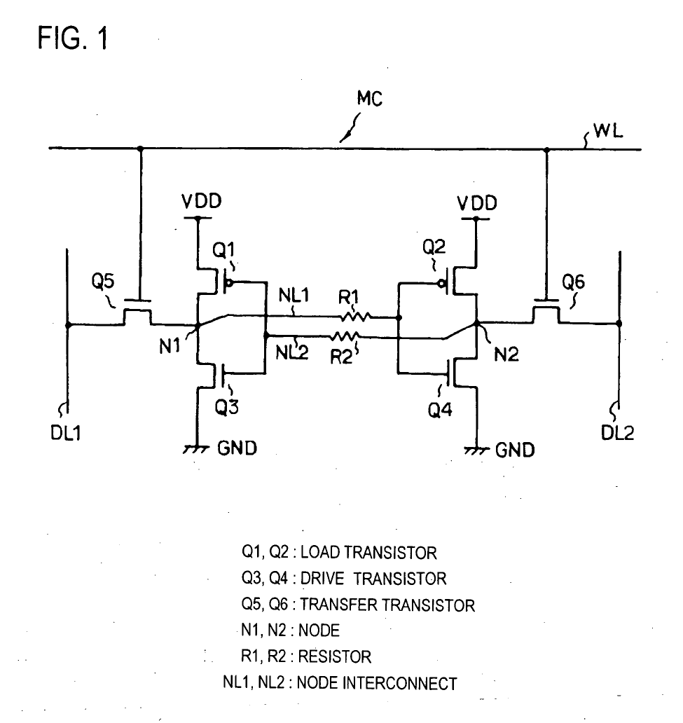

FIG. 1 shows an equivalent circuit of a semiconductor device of the present invention. The semiconductor device in this embodiment is a SRAM including six MOS (metal oxide semiconductor) transistors so called a 6Tr memory cell (hereinafter simply referred to as a memory cell MC).

The memory cell MS includes a pair of drive transistors Q3 and Q4, a pair of load transistors Q1 and Q2, and a pair of transfer transistors Q5 and Q6. Both of the drive transistors Q3 and Q4 are N-MOS transistors (N-channel transistor). Both of the load transistors Q1 and Q2 are P-MOS transistors (P-channel transistor). The source or drain of the load transistors Q1 and Q2 are connected in serial to the source or drain of the drive transistors Q3 and Q4, respectively. The transfer transistors Q5 and Q6 are N-MOS transistors (N-channel transistor). The source or drain of the transfer transistors Q5 and Q6 are connected to nodes N1 and N2 which are connection point of the transistors Q1 and Q3, and transistors Q2 and Q4, respectively.

As for the load transistor Q1, the source is connected to the power source VDD, the drain is connected to the drain of the drive transistor Q3, and the gate is connected to the gate of the drive transistor Q3. As for the drive transistor Q3, the source is grounded (connected to ground GND). The drain of the drive transistor Q3 is connected to the digit line DL1 via the transfer transistor Q5.

As for the load transistor Q2, the source is connected to the power source VDD, the drain is connected to the drain of the drive transistor Q4, and the gate is connected to the gate of the drive transistor Q4. As for the drive transistor Q4, the source is grounded (connected to ground GND). The drain of the drive transistor Q4 is connected to the digit line DL2 via the transfer transistor Q6.

The drain of the drive transistor Q3 is connected to the gate of the drive transistor Q4 via the node interconnect NL1 on which a resistor R1 is provided. The drain of the drive transistor Q4 is connected to the gate of the drive transistor Q3 via the node interconnect NL2 on which a resistor R2 is provided.

The gates of the transfer transistors Q5 and Q6 are connected to the word line WL, respectively.

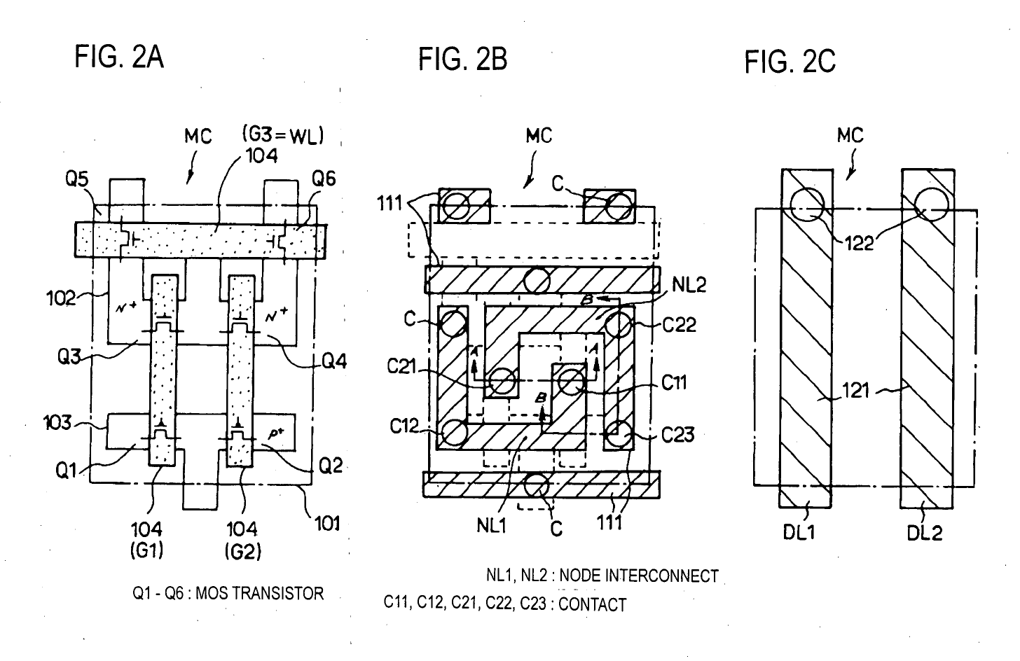

FIGS. 2A, 2B, and 2C show layouts of the semiconductor device 100 including the memory cell MC as described in FIG. 1.

FIG. 2A shows a structure including an N-type diffusion layer 102, a P-type diffusion layer 103, and three polysilicon (polycrystalline silicon) layers 104 formed on a substrate 101. The N-type diffusion layer 102 and the P-type diffusion layer 103 are respectively formed to have a predetermined pattern. Each of the polysilicon layers 104 is formed on the N-type diffusion layer 102 or the P-type diffusion layer 103 such that each of the polysilicon layers 104 crosses the N-type diffusion layer 102 or the P-type diffusion layer 103.

The gates (G1, G2, G3) of the transistors Q1 to Q6 and the word line WL (where WL=G3) are formed by the polysilicon layer 104. The N-MOS transistors Q3 to Q6 are formed by the N-type diffusion layer 102 and the polysilicon layer 104. The P-MOS transistors Q1 and Q2 are formed by the P-type diffusion layer 103 and the polysilicon layer 104.

FIG. 2B shows a structure, which is formed on the structure shown in FIG. 2A, including first interconnect layers 111 formed by aluminum layers and connected to the N-type diffusion layer 102, the P-type diffusion layer 103, and the polysilicon layers 104 via the contacts C (including contacts C11, C12, C21, and C22).

The first interconnect layer 111 connects, at its part, the P-MOS transistor Q1 and the N-MOS transistor Q3 with the P-MOS transistor Q2 and the N-MOS transistor Q4. Especially, the part between the contacts C11 and C12, and the part between the contacts C21 and C22 of the first interconnect layer 111 function as the node interconnect NL1 and the node interconnect NL2, respectively.

FIG. 2C shows a structure, which is formed on the structure shown in FIG. 2B, including a second inter connect layers 121 which serve as the digit lines DL1 and DL2. The second inter connect layers 121 are formed on the first inter connect layers 111 and connected therewith through the via plugs 122.

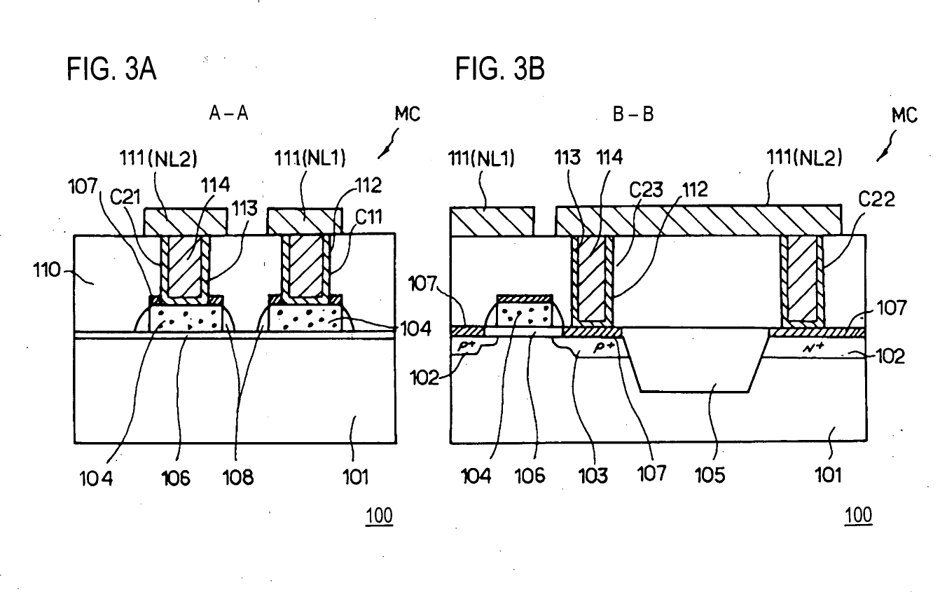

FIGS. 3A and 3B show cross sectional views of A-A line and B-B line of the structure shown in FIGS. 2A to 2C, respectively.

FIG. 3A shows the structure of the contacts C11 and C21 formed under the first interconnect layer 111. FIG. 3B shows the structure of the contacts C22 and C23 formed under the first interconnect layer 111.

As shown in FIG. 3B, the N-type diffusion layer 102 and the P-type diffusion layer 103 are isolated by the isolation layer 105 which is formed on a surface of the silicon substrate 101. The semiconductor device 100 further includes a gate insulator 106 and a polysilicon layer 104 formed on the gate insulator 106. The gate electrodes G1, G2, and G3 (word line WL) are formed by the gate insulator 106 and the polysilicon layer 104. There is provided a silicide layer 107, constituted of Ti, Co and the like, on a surface of the polysilicon layer 104. With the silicide layer 107, the resistance of the polysilicon layer 104 is lowered. In this embodiment, the silicide layers 107 are formed on the surface of the N-type diffusion layer 102 and the P-type diffusion layer 103, respectively. Thus, the resistance of the N-type diffusion layer 102 and the P-type diffusion layer 103 are lowered as well.

In addition, the semiconductor device 100 further includes side walls 108 constituted of insulating films formed at the side of the polysilicon layer 104, and an inter layer dielectric 110 provided with contact holes 112, formed on the entire surface of the silicon substrate 101. The contacts C are respectively formed in the contact holes 112. Each of the contacts C is formed with a barrier metal layer 113, constituted of TiN/Ti, formed on the inside surface of the contact holes 112 and a contact plug 114, constituted of W (tungsten), formed on the barrier metal layer 113 to fill the contact hole 112.

As for the contacts C11 and C21, the silicide layers 107 are removed at the regions below the contact holes 112 such that the barrier metal layers 113 are directly connected to the polysilicon layers 104 without having the silicide layers 107 interposed therebetween, respectively.

The node interconnects NL1 and NL2 are formed by the part of the first interconnect layer 111 formed on the barrier metal layer 113 and the contact plug 114. In this case, the resistor R1 and R2 provided on the node interconnects NL1 and NL2 are actualized by the contact resistance of the polysilicon layers 104 and the contacts C11 and C12, respectively.

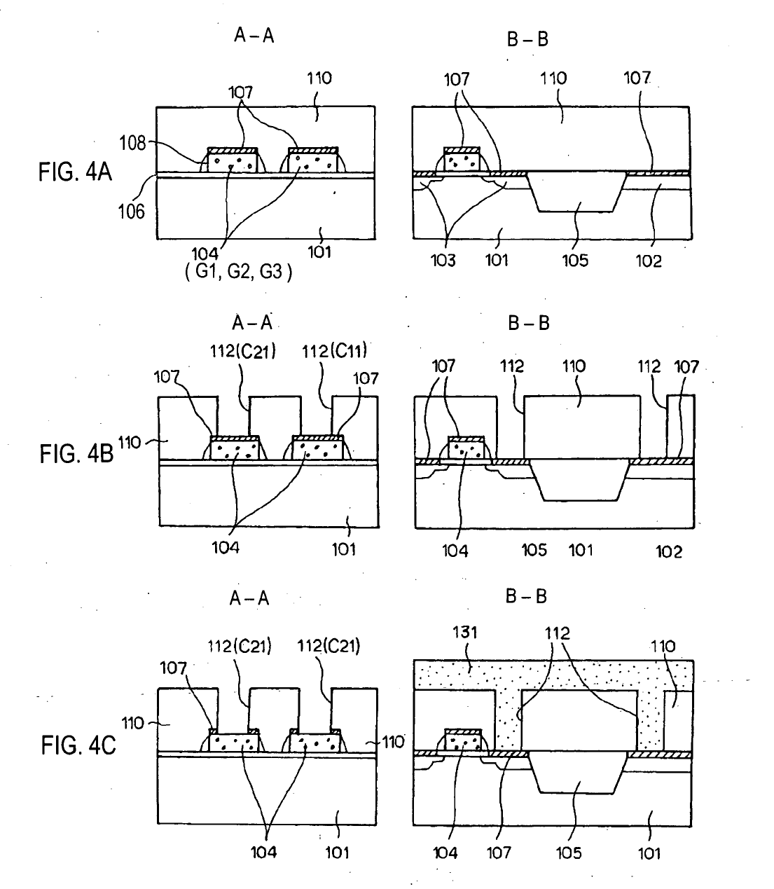

FIGS. 4A to 4C are cross sectional views of the semiconductor device as described above, showing the manufacturing process of the memory cell MC. In FIGS. 4A to 4C, the area “A-A” corresponds to FIG. 3A, and the area “B-B” corresponds to FIG. 3B.

As shown in FIG. 4A, the isolation layer 105 is formed on the silicon substrate 101. Then, the gate insulator 106 is formed on the entire surface of the silicon substrate 101. Subsequently, the polysilicon layer 104 is formed on the gate insulator 106. The polysilicon layer 104 is selectively patterned to form the gate electrodes G1, G2, and G3 (word line WL). Then, the side walls 108 are formed at the side surface of the gate electrodes. Subsequently, the gate electrodes and the side walls are used as masks for a self alignment process to form the N-type diffusion layer 102 and the P-type diffusion layer 103 by implanting impurities. Then, Ti and Co are formed on the entire surface of the silicon substrate 101 and the silicon substrate 101 is heated to form the silicide layer 107 on the polysilicon layer 104, the N-type diffusion layer 102 and the P-type diffusion layer 103. Then, the inter layer dielectric 110 is formed on the silicon substrate 101.

Subsequently, as shown in FIG. 4B, there are provided contact holes 112 at predetermined regions of the inter layer dielectric 110. The contact holes 112 are formed until the surface of the silicide layers 107 are exposed. The contact holes are formed on the polysilicon layers 104, N-type diffusion layer 102 and the P-type diffusion layer 103.

Then, as shown in FIG. 4C, the contact holes 112 formed on the N-type diffusion layer 102 and the P-type diffusion layer 103 are covered by the resist mask 131 constituted of photo resist. Then, the inter layer dielectric 110 formed with the contact holes 112 is used as a mask for a self alignment process to etch the exposed silicide layer 107 formed on the polysilicon layers 104 by dry etching, wet etching, or combination thereof. With this process, the silicide layers 107 formed on the polysilicon layers 104 are removed only at the bottom of the contact holes 112 (C11 and C21) to have the polysilicon layers 104 exposed at these regions. Then, the resist mask 131 is removed.

As shown in FIGS. 3A and 3B, the barrier metal layer 113 is formed on the silicon substrate 101 by sputtering Ti/TiN, and the contact plug 113 constituted of W is formed on the barrier metal layer 113 by CVD (chemical vapor deposition). Then, CMP (chemical mechanical polishing) is performed to remove surplus of the Ti/TiN layer and the W layer located outside the contact holes 112. Subsequently, the aluminum layer is formed on the inter layer dielectric 110. The aluminum layer is patterned in a predetermined pattern to form the first interconnect layers 111. Although it is not described in FIGS. 3A and 3B, a second inter layer dielectric, contacts formed in the second inter layer dielectric, and a second interconnect layer are formed on the first interconnect layers 111 and the second interconnect layer is patterned in a predetermined pattern such that the second interconnect layers 121 (digit lines DL1 and DL2) shown in FIG. 2C is connected to the respective first interconnect layers 111 through the via plug 122 (shown in FIG. 2C). Thus, the memory cell MC is formed.

According to the semiconductor device including the memory cell MC of the present embodiment, the resistance of the gate electrodes G1 and G2 of each of the MOS transistors Q1 to Q4 can be lowered as the silicide layer 107 is formed on each of the polysilicon layers 104. In addition, the resistance of the gate electrodes G3 of the each of the MOS transistors Q5 and Q6 can be lowered as the silicide layer 107 is formed on each of the polysilicon layers 104, as well.

Furthermore, as the contacts C11 and C21 are connected directly to the polysilicon layers 104 without having the silicide layers 107 interposed therebetween, thus the contact resistance between the contacts C11 and C21 and the polysilicon layers 104 become higher compared with the case when the silicide layers 107 are formed between the contacts C11 and C21 and the polysilicon layers 104. Therefore, the resistors R1 and R2 shown in FIG. 1 can be obtained with this structure.

The contact resistance of the polysilicon layers 104 and the first interconnect layers 111 connected via the contacts C other than the contacts C11 and C12 can be lowered as the silicide layers 107 are not removed thereunder.

In addition, according to the manufacturing process of the present embodiment, the silicide layer 107 formed on the polysilicon layer 104 is etched with the inter layer dielectric 110 provided with the contact holes 122 used as the masks for a self alignment process. Thus, the high accuracy lithography techniques those required in the conventional arts described in the above publications are not necessary in this embodiment. Therefore, the semiconductor device 100 of the present embodiment can be obtained with a simple manufacturing process. In addition, by using the self alignment process, margin regions are not necessary. Therefore, the size of the memory cell is not increased by introducing the technique of the present embodiment.

### Second Embodiment

The semiconductor device 100 of the present embodiment has same circuit structure as that shown in FIG. 1. The semiconductor device 100 of the present embodiment has same structure as that of the first embodiment except that it includes an etching stopper formed on the inter layer dielectric 110.

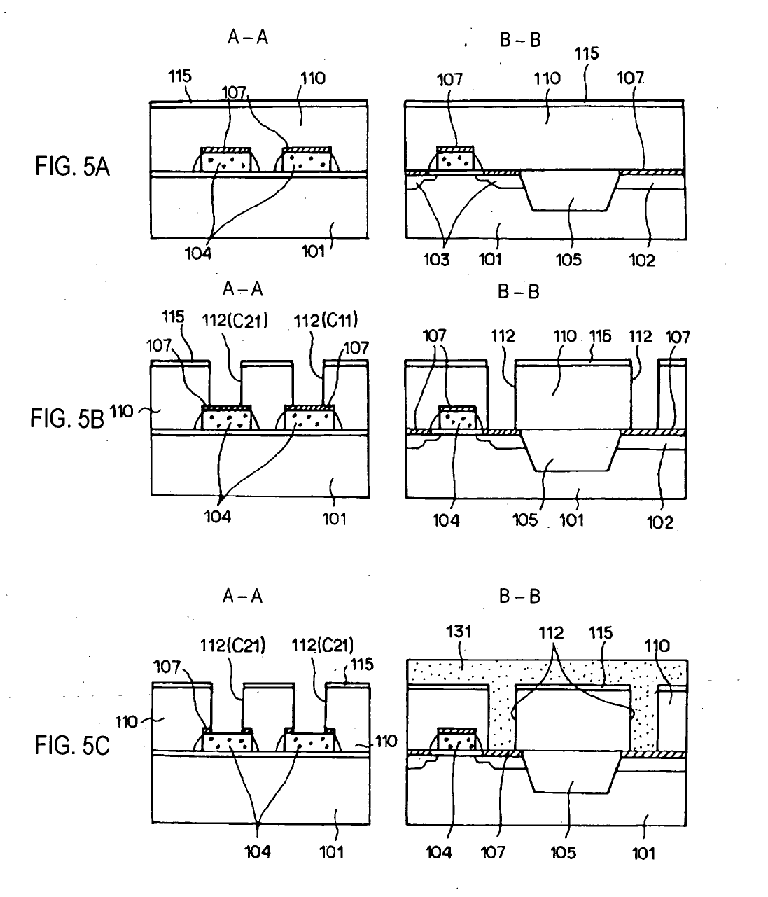

FIGS. 5A to 5C are cross sectional views of the semiconductor device of the present embodiment, showing the manufacturing process of the memory cell MC.

As shown in FIG. 5A, the semiconductor device is formed in accordance with a same process as described in the first embodiment with reference to FIG. 4A. Then, the etching stopper 115 is formed on the inter layer dielectric 110. The etching stopper 115 may be constituted of a material which has high etching selectively to the silicide layer 107 and the inter layer dielectric 110 such that this functions to protect the surface of the inter layer dielectric 110 when the silicide layer 107 is etched in the following process.

Then, as shown in FIG. 5B, the etching stopper 115 and the inter layer dielectric 110 are selectively etched to form the contact holes 112 at predetermined regions thereof. With this process, the silicide layers 107 formed at the bottom of each of the contact holes 112 are selectively exposed.

Then, as shown in FIG. 5C, same as described in the first embodiment, the contact holes 112 formed on the N-type diffusion layer 102 and the P-type diffusion layer 103 are covered by the resist mask 131. Subsequently, the etching stopper 115 and the inter layer dielectric 110 formed with the contact holes 112 are used as a mask for a self alignment process to etch the exposed silicide layer 107 formed on the polysilicon layers 104 by dry etching, wet etching, or combination thereof. With this process, the silicide layers 107 formed on the polysilicon layers 104 are removed only at the bottom of the contact holes 112 (C11 and C21) to have the polysilicon layers 104 exposed at these regions.

The above process is almost same as those described in the first embodiment and the semiconductor device having the memory cell shown in FIGS. 3A and 3B can be obtained. The same merits as described in the first embodiment can be obtained in this embodiment as well.

In addition, as the etching stopper 115 is formed on the inter layer dielectric 110, the damage by the etching liquid or etching gas to the part of the inter layer dielectric 110 where the resist mask 131 is not formed can be prevented. Thus, the shape of the inter layer dielectric 110 is maintained, and the shape of the contact can be maintained. Therefore, the semiconductor device with a high reliability can be obtained.

The present invention can be adaptable not only to the resistor of the memory cell of the SRAM as described in the embodiments, but also to any interconnect which has a salicide structure including a silicide layer formed on a polysilicon layer, wherein a contact having a resistor thereon is connected to the silicide layer. In this case, the structure in which the contact is directly connected to the silicide layer can be simply obtained by etching the silicide layer formed at the bottom of the contact hole formed in the inter layer dielectric through a self alignment process.

Although the present invention has been described referring to the preferable embodiment, it is apparent to those skilled in the art that the embodiment is only exemplary, and that various modifications may be made without departing from the scope of the present invention.

1. A semiconductor device, comprising:
a conductive layer having a connection region where a salicide is not formed, said conductive layer further having a salicide structure which surrounds at least a part of said connection region;
a contact plug, a bottom surface of which is formed on said connection region and a side surface of which is in contact with said salicide structure; and
an interconnect layer coupled to said contact plug.

2. The device as set forth in claim 1, wherein said conductive layer is a gate electrode of a static random access memory (SRAM) cell.

3. The device as set forth in claim 2, wherein said SRAM cell has a pair of drive transistors, said interconnect layer is coupled between one of said drive transistors and the other of said drive transistors.

4. A semiconductor device, comprising:
a conductive layer which has a salicide structure including a semiconductor layer, and a silicide layer formed on a surface of said semiconductor layer other than a connection region; and
a contact formed on said connection region of said conductive layer for connecting said conductive layer to an upper interconnect.

5. The semiconductor device as set forth in claim 4, wherein said conductive layer is a gate electrode of a MOS transistor.

6. The semiconductor device as set forth in claim 4, further comprising a memory cell which has a SRAM structure including a pair of drive transistors where the gate electrode of one of said pair of drive transistors is connected to the drain of the other of said pair of drive transistors via a node interconnect on which a resistor is provided,
wherein said conductive layer is said gate electrode of said one of said pair of drive transistors and said contact is said node interconnect formed on said gate electrode.

7. The semiconductor device as set forth in claim 4, further comprising an inter layer dielectric formed on said conductive layer to cover thereof, wherein said inter layer dielectric is provided with a contact hole and said connection region of said conductive layer is defined by the pattern of said inter layer dielectric.

8. The semiconductor device as set forth in claim 7, further comprising an etching stopper, constituted of a material which has high etching selectively to said silicide layer, formed on said inter layer dielectric, wherein said etching stopper is formed to have same shape as that of said inter layer dielectric.

9. The semiconductor device as set forth in claim 5, further comprising an inter layer dielectric formed on said conductive layer to cover thereof, wherein said inter layer dielectric is provided with a contact hole and said connection region of said conductive layer is defined by the pattern of said inter layer dielectric.

10. The semiconductor device as set forth in claim 9, further comprising an etching stopper, constituted of a material which has high etching selectively to said silicide layer, formed on said inter layer dielectric, wherein said etching stopper is formed to have same shape as that of said inter layer dielectric.

11. The semiconductor device as set forth in claim 6, further comprising an inter layer dielectric formed on said conductive layer to cover thereof, wherein said inter layer dielectric is provided with a contact hole and said connection region of said conductive layer is defined by the pattern of said inter layer dielectric.

12. The semiconductor device as set forth in claim 11, further comprising an etching stopper, constituted of a material which has high etching selectively to said silicide layer, formed on said inter layer dielectric, wherein said etching stopper is formed to have same shape as that of said inter layer dielectric.

13. A method for manufacturing a semiconductor device, comprising:
forming a conductive layer which has a salicide structure including a semiconductor layer, and a silicide layer formed on a surface of said semiconductor layer;
forming an inter layer dielectric on said conductive layer to cover said conductive layer;
forming a contact hole in said inter layer dielectric to expose a part of said silicide layer of said conductive layer;
etching said exposed silicide layer with using said inter layer dielectric as a mask for a self alignment process to remove said part of said silicide layer; and
forming a contact in said contact hole for connecting said conductive layer to an upper inter connect.

14. The method for manufacturing a semiconductor device as set forth in claim 13, wherein said semiconductor device including a memory cell which has a SRAM structure having a pair of drive transistors where the gate electrode of one of said pair of drive transistors is connected to the drain of the other of said pair of drive transistors via a node interconnect on which a resistor is provided,
said forming a conductive layer including forming a plurality of transistors each including a gate electrode which has a salicide structure including a semiconductor layer, and a silicide layer formed on a surface of said semiconductor layer, and source and drain regions, said plurality of transistors including said pair of drive transistors;
said forming an inter layer dielectric including forming an inter layer dielectric on said plurality of transistors;
said forming a contact hole including forming a contact hole in said inter layer dielectric to expose a part of said silicide layer of said gate electrode of said drive transistor;
said etching said exposed silicide layer including etching said exposed silicide layer with using said inter layer dielectric as a mask for a self alignment process to remove said part of said silicide layer; and
said forming a contact including forming a contact which is electrically connected to said gate electrode in said contact hole and functions as said node interconnect.

15. The method for manufacturing a semiconductor device as set forth in claim 14, wherein a plurality of contact holes are formed in said forming a contact hole, and said method further comprising: forming a mask to cover said plurality of contact holes other than said contact hole formed on said part of said silicide layer of said gate electrode of said drive transistor; and removing said mask after said etching said exposed silicide layer.

16. The method for manufacturing a semiconductor device as set forth in claim 14, further comprising forming an etching stopper, constituted of a material which has high etching selectively to said silicide layer, on said inter layer dielectric, wherein said contact hole is formed in said etching stopper as well in said forming a contact hole.

17. The method for manufacturing a semiconductor device as set forth in claim 15, further comprising forming an etching stopper, constituted of a material which has high etching selectively to said silicide layer, on said inter layer dielectric, wherein said contact hole is formed in said etching stopper as well in said forming a contact hole.
